(19) United States
(12) Patent Application Publication
(10) Pub. No.: US 2026/0324014 A1
(43) Pub. Date: Oct. 15, 2026

(54) POWER SEMICONDUCTOR DEVICE AND PREPARATION METHOD THEREFOR

(71) Applicant: GlenFly Tech Co., Ltd., Shanghai (CN)

(72) Inventors: Tao ZHANG, Shanghai (CN); Na LI, Shanghai (CN)

(21) Appl. No.: 19/098,199

(22) Filed: Apr. 2, 2025

(30) Foreign Application Priority Data
Feb. 10, 2025 (CN) 202510148280.9

(51) Int. Cl. H10D 62/10; H10D 12/00; H10D 12/01; H10D 64/00

(52) U.S. Cl. CPC H10D 62/111; H10D 12/032; H10D 12/441; H10D 62/112; H10D 64/112

(57) ABSTRACT

Power semiconductor device includes: substrate, including cell region and terminal region; main junction structure, locating in cell region; plurality of field limiting ring structures, locating in terminal region, isolated in first direction pointing from cell region to terminal region, including at least one first field limiting ring and at least one cutoff ring located on one side of first field limiting ring in first direction; first insulating layer, locating on side of both main junction structure and field limiting ring structures away from substrate; electrode layer, locating on side of first insulating layer away from substrate, including first field plate covering portion of main junction structure close to field limiting ring structures and at least one first field limiting ring close to main junction structure; first field plate electrically connecting with main junction structure. Present application improves maximum breakdown voltage and reliability against dielectric breakdown of device.

### CROSS-REFERENCES TO RELATED APPLICATION

The present invention claims the priority of Chinese Patent Application No. 2025101482809, filed on Feb. 10th, 2025. The contents of the above application are incorporated herein by reference.

### FIELD OF TECHNOLOGY

The present application relates to the technical field of semiconductor, and more specifically, to a power semiconductor device and a preparation method therefor.

### BACKGROUND

In the prior art, a power semiconductor device, as one of a core and basic device of an electronic power technology, plays a vital role in a plurality of fields including energy, manufacturing, transportation, consumer electronics and more. An insulated gate bipolar transistor (IGBT) is a typical power semiconductor device, having a plurality of advantages including a low conduction voltage drop, a high input impedance, a fast switching speed, a small switching loss and more, having been widely applied to a plurality of fields including energy, traffic, information, medical treatment and more. In an electric vehicle, which is currently a hotspot, the IGBT acts as a core module in a driving system, which costs about 10% of a whole vehicle, and even a charging pile thereof is also dominated by the IGBT, which accounts for about 20% of a cost thereof.

The IGBT is often applied to a high-voltage application scenario, requiring a certain voltage level and reliability. For a cylindrical junction or a planar junction in a cell of the IGBT, due to an insufficient curvature, an electric field will be concentrated, causing a dielectric breakdown easy to occur, thus a field limiting ring is often attached to a terminal to weaken a phenomenon of the electric field concentration; further, allocating the electric field in a terminal area is able to improve an overall breakdown voltage, so as to meet a user demand.

In the prior art, a commonly used field limiting ring, forms a spherical junction at a corner in a layout, having an electric field intensity much larger than that of the cylindrical junction, also for the main junction structure and a first field limiting ring, due to a curvature radius thereof is smallest among all of the field limiting rings, thus it is most likely to have a breakdown occur at the corner, resulting in a device failure. In general, the field limiting ring will be matched with a field plate (a poly-silicon field plate or a metal field plate) to optimize the electric field.

In the prior art, when a device is in an actual application, the field limiting ring-field plate in the device may have a distribution change of a surface electric field of the device due to an interface state (including a defect, a charge, or more) change, especially for a curved junction on an edge of the main junction structure in the device, at the corner in the layout, due to forming a spherical junction, and having a minimum curvature radius, thus it is easy to have a breakdown occur, resulting in a device failure. In addition, when an additional process is applied to addressing a problem on a reliability against a dielectric breakdown, it will in turn increase a process cycle and a cost.

### SUMMARY

The technical problem to be solved by the present application is to provide a power semiconductor device and a preparation method therefor, which can improve a maximum breakdown voltage and reliability against dielectric breakdown of a device in use, by optimizing a structure of the field plate.

In order to solve the technical problem stated above, a first aspect of the present application, in an embodiment, provides a power semiconductor device, wherein comprising:
a substrate, the substrate being divided into a cell region and a terminal region, while the terminal region being located at a periphery of the cell region;
a main junction structure, arranged on a first side of the substrate and located in the cell region;
a plurality of field limiting ring structures, arranged on the first side of the substrate and located in the terminal region, while being arranged in an isolated manner in a first direction, wherein the first direction is a direction pointing from the cell region to the terminal region;
the plurality of field limiting ring structures comprising at least one first field limiting ring and at least one cutoff ring, while the at least one cutoff ring being arranged on one side of the at least one first field limiting ring in the first direction;
a first insulating layer, arranged on a side of both the main junction structure and the plurality of field limiting ring structures away from the substrate;
an electrode layer, arranged on a side of the first insulating layer away from the substrate, the electrode layer comprising a first field plate, the first field plate covering one portion of the main junction structure close to the plurality of field limiting ring structures, and covering at least one first field limiting ring close to the main junction structure;
the first field plate being connected electrically to the main junction structure.

In an implementation, an amount of the at least one field limiting ring covered by the first field plate is determined according to a minimum breakdown voltage value of the power semiconductor device. In an implementation, the first field plate covers one of the at least one first field limiting ring; or the first field plate covers two of the at least one first field limiting ring.

In an implementation, the plurality of field limiting ring structures further comprise: at least one second field limiting ring, arranged between the at least one first field limiting ring and the cutoff ring, and arranged in an isolated manner in the first direction; the electrode layer may further comprise: at least one second field plate, arranged on the side of the first insulating layer away from the substrate and insulated from the first field plate in the first direction, having an amount as same as an amount of the at least one second field limiting ring, and the at least one second field plate is electrically connected to the at least one second field limiting ring in a one-to-one correspondence manner; for each pair of the at least one second field plate and the at least one second field limiting ring having been electrically connected, the at least one second field plate covering at least a portion of the at least one second field limiting ring corresponding thereto.

In an implementation, the electrode layer further comprises: at least one third field plate, arranged on the side of the first insulating layer away from the substrate; the first field plate, the at least one second field plate and the at least one third field plate being insulated from each other in the first direction, an amount of the at least one third field plate being as same as an amount of the at least one cutoff ring, the at least one third field plate and the at least one cutoff ring being connected electrically to each other in a one-to-one correspondence; for each pair of the at least one third field plate and the at least one cutoff ring having been electrically connected, the at least one third field plate covering at least a portion of the at least one cutoff ring corresponding thereto.

In an implementation, the power semiconductor device further comprises: a plurality of contacts penetrating through the first insulating layer, comprising a first contact, at least one second contact and at least one third contact, the first field plate being in contact with the main junction structure through the first contact, each of the at least one second field plate is in contact with a different second field limiting ring through a different second contact, and each of the at least one third field plate being in contact with a different cutoff ring through a different third contact.

In an implementation, the first insulating layer comprises: a plurality of silicon local oxidation isolation structures and a plurality of contact portions, the plurality of silicon local oxidation isolation structures and the plurality of contact portions being arranged alternately; between adjacent two structures of the plurality of field limiting ring structures and the main junction structure, there is one of the plurality of silicon local oxidation isolation structures arranged respectively, each structure of the plurality of field limiting ring structures and the main junction structure has one of the plurality of contact portions arranged, each of the plurality of contacts penetrating through a different contact portion of the plurality of contact portions.

In an implementation, the power semiconductor device may further comprise: a second insulating layer, arranged on the side of the first insulating layer away from the substrate, comprising a plurality of insulating portions, arranged respectively between adjacent two field plates of the first field plate, the at least one second field plate, and the at least one third field plate.

A second aspect according to an embodiment of the present application, provides a preparation method for the power semiconductor device, applied to preparing the power semiconductor device stated above, wherein comprising: providing the substrate; forming the main junction structure and the plurality of field limiting ring structures on a surface of the first side of the substrate; forming the first insulating layer on the side of both the main junction structure and the plurality of field limiting ring structures away from the substrate; forming the electrode layer on the side of the first insulating layer away from the substrate. In an implementation, when the power semiconductor device comprises a plurality of contacts and the first insulating layer comprises a plurality of contact portions, after forming the first insulating layer on the side of both the main junction structure and the plurality of field limiting ring structures away from the substrate, but before forming the electrode layer on the side of the first insulating layer away from the substrate, the power semiconductor device further comprises: adopting a punching process to punch the contact portion to form a plurality of through holes; depositing a metal material into the plurality of through holes to form the plurality of contracts, wherein both a process of depositing the metal material into the plurality of through holes to form the plurality of contracts, and a process of forming the electrode layer on the side of the first insulating layer away from the substrate are performed in a same process.

Comparing the prior art, the technical solution of the present application may achieve at least the following beneficial effects:
since the power semiconductor device comprises:
the substrate; the main junction structure;
the plurality of field limiting ring structures;
the first insulating layer and the electrode layer;
the substrate is divided into the cell region and the terminal region;
the terminal region is arranged at the periphery of the cell region;
the main junction structure is arranged on the first side of the substrate and located in the cell region;
the plurality of field limiting ring structures are arranged on the first side of the substrate and located in the terminal region;
the plurality of field limiting ring structures are arranged in the isolated manner along the first direction;
the first direction is the direction pointing from the cell region to the terminal region;
the plurality of field limiting ring structures comprise at least one first field limiting ring and at least one cutoff ring, the at least one cutoff ring is arranged on the side of the at least one first field limiting ring in the first direction, the first insulating layer is arranged on the side of both the main junction structure and the plurality of field limiting ring structures away from the substrate;
the electrode layer comprises the first field plate, the first field plate covers both a portion of the main junction structure close to the plurality of field limiting ring structures and one or two of the at least one first field limiting ring close to the main junction structure, the first field plate is connected electrically to the main junction structure, instead of connecting electrically to the first field limiting ring covered thereby. In such a way, when the device is in use, a voltage of a field plate of the first field limiting ring is a voltage of a field plate of the main junction structure, that is, 0 Volt, which equals to applying a higher negative voltage to a bias field plate (the first field plate), being able to further reduce a peak value of the electric field near a surface of the main junction. Moreover, since the first field plate covers a larger area, an effective area acting on a surface of the substrate is also increased, resulting in more carriers being rejected, thereby reducing the peak value of the electric field near a surface of a main junction. Meanwhile, an electric field intensity inside the substrate will be improved, thereby a maximum breakdown voltage of the device will also be improved in a whole.

Moreover, since the main junction structure and a plurality of field limiting rings close to the cell region have a short distance from the cell, an electric field at a corner of the field limiting ring and a corner of an edge of the main junction structure in the layout is larger, having a stronger distortion, thus a destructive breakdown is more likely to occur. In the present application, the maximum peak of the surface electric field is transferred from the edge of the main junction structure to the first field limiting ring, the second field limiting ring, or a plurality of other field limiting rings, it is able to increase a distance between the maximum peak of the surface electric field and the cell, increase a radius of curvature of the corner at the maximum peak of the surface electric field, thus being able to further reduce the maximum peak of the electric field at a corner of the device, reduce an occurrence of dielectric breakdown, and improve the reliability of the device against the dielectric breakdown.

All above, the technical solution provided by the present application, by optimizing the structure of the field plate, is able to improve the maximum breakdown voltage and the reliability against the dielectric breakdown of the device in use.

In addition, a process flow for preparing the power semiconductor device provided in the present application is not increased, but having a same process flow for preparing the power semiconductor device in the prior art, thus a process cycle or a cost is not increased.

### BRIEF DESCRIPTION OF THE DRAWINGS

FIG. 1 illustrates a schematic structural diagram on a power semiconductor device according to an embodiment of the present application.

FIG. 2 illustrates a schematic structural diagram on a power semiconductor device in the prior art;

FIG. 3 illustrates a schematic diagram on a one-dimensional electric field distribution comparison between the power semiconductor device shown in FIG. 1 and the insulated gate bipolar transistor shown in FIG. 2;

FIG. 4 illustrates a schematic structural diagram on a power semiconductor device according to another embodiment of the present application.

FIG. 5 illustrates a schematic diagram on comparing a one-dimensional electric field distribution between the power semiconductor device shown in FIG. 4 and the insulated gate bipolar transistor shown in FIG. 2;

FIG. 6 illustrates a flow chart on a preparation method of a power semiconductor device according to another embodiment of the present application;

FIG. 7 illustrates an extended flow chart on a preparation method of a power semiconductor device according to another embodiment of the present application;

Wherein: 11-substrate; 12-main junction structure; 13-field limiting ring structure; 131-first field limiting ring; 132-second field limiting ring; 134-cutoff ring; 14-first insulating layer; 141-silicon local oxidation isolation structure; 142-contact portion; 15-electrode layer; 151-first field plate; 152-second field plate; 153-third field plate; 16-cutoff layer; 17-collactor region; 18-contact; 181-first contact; 182-second contact; 183-third contact; 19-second insulating layer.

### DESCRIPTION OF THE EMBODIMENTS

Unless otherwise defined, technical or scientific terms used in the present specification and claims shall have the common meanings as understood by those skilled in the art to which the present application belongs. The specific embodiments of the present application will be described below in conjunction with the accompanying drawings. It should be pointed out that in the specific description process of these embodiments, in order to provide a concise and clear description, this specification cannot provide a detailed description of all the features of the actual embodiments. Without departing from the spirit and scope of the present application, those skilled in the art may modify and replace the embodiments of the present application, and the resulting embodiments are also within the scope of protection of the present application.

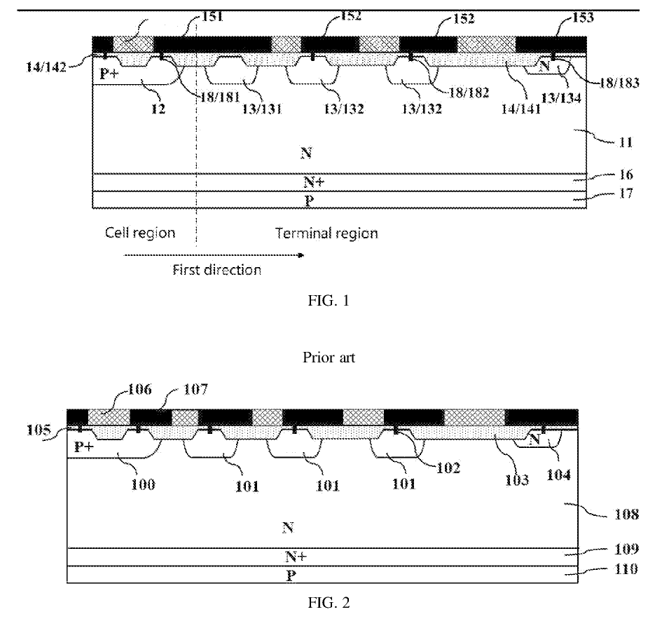

An embodiment of the present application provides a power semiconductor device. The power semiconductor device may be an insulated gate bipolar transistor (IGBT), but is not limited thereto. Shown as FIG. 1, the power semiconductor device comprises a substrate 11, a main junction structure 12, a plurality of field limiting ring structures 13, a first insulating layer 14, and an electrode layer 15.

Shown as FIG. 1, the substrate 11 is divided into a cell region and a terminal region, while the terminal region is located at a periphery of the cell region.

In an embodiment, a conductivity type of the substrate 11 may be a first conductivity type (eg, N-type), but is not limited thereto. The substrate 11 is applied to providing a drift region in a first conductivity type.

In an embodiment, shown as FIG. 1, the substrate 11 comprises a cutoff layer 16 and a collector region 17 cutoff layer 16. The cutoff layer 16 is a field stop layer (FS layer), a conductive type of the cutoff layer 16 may be a first conductivity type (for example, an N-type), and a doping concentration thereof is greater than a doping concentration of the substrate 11, that is, the cutoff layer 16 is an N+ type cutoff layer. A conductivity type of the collector region 17 may be a second conductivity type (for example, a p-type), but is not limited thereto.

In an embodiment, shown as FIG. 1, the main junction structure 12 is arranged on a first side of the substrate 11 and located in the cell region. A conductivity type of the main junction structure 12 may be a second conductivity type (eg, P-type), the main junction structure 12 may be a P + type main junction structure 12, which is generally obtained by implanting a P-type doping into the substrate 11, and the P-type doping may be Boron ions or gallium (Ga) ions, but is not limited thereto. The main junction structure 12 may be connected to an emitter through a metal electrode.

In an embodiment, shown as FIG. 1, the plurality of field limiting ring structures 13 are arranged on a first side of the substrate 11 and located in the terminal region. The plurality of field limiting ring structures 13 are arranged in an isolated manner in the first direction, and the first direction is a direction from the cellular region to the terminal region. Shown as FIG. 1, the plurality of field limiting ring structures 13 comprise at least one first field limiting ring 131 and at least one cutoff ring 134, and the at least one cutoff ring is located on one side of the at least one first field limiting ring 131 in the first direction. In an embodiment, shown as FIG. 1, the plurality of field limiting ring structures 13 comprise one first field limiting ring 131 and one cutoff ring 134, while the first field limiting ring 131 and the cutoff ring 134 are arranged in an isolated manner in the first direction.

In an embodiment, shown as FIG. 1, the first insulating layer 14 is located on a side of the main junction structure 12 and the plurality of field limiting ring structures 13 away from the substrate 11. A material of the first insulating layer 14 may be silicon oxide, but is not limited thereto.

In an embodiment, shown as FIG. 1, the first insulating layer 14 comprises a plurality of silicon local oxidation isolation structures 141 and a plurality of contact portions 142.

Shown as FIG. 1, the silicon local oxidation isolation structure 141 and the contact portion 142 are alternately arranged, and a thickness of the silicon local oxidation isolation structure 141 is greater than a thickness of the contact portion 142. There is a silicon local oxidation isolation structure 141 arranged between adjacent two structures of the main junction structure 12 and the plurality of field limiting ring structures 13, while the silicon local oxidation isolation structure 141 is applied to isolating adjacent two structures. There is a contact portion 142 on each structure of the main junction structure 12 and the plurality of field limiting ring structures 13.

In an embodiment, the silicon local oxidation isolation structure 141 may be prepared by a local oxidation of silicon (LOCOS) process. A surface of the silicon local oxidation isolation structure 141 away from the substrate 11 may be a plane. The silicon local oxidation isolation structure 141 shown in FIG. 1 is obtained by using the LOCOS process to prepare an initial isolation structure before performing a chemical mechanical polishing (CMP) on the initial isolation structure.

In another embodiment, the silicon local oxidation isolation structure 141 may be an initial isolation structure prepared by using an LOCOS process, a complete initial isolation structure without a CMP process.

In an embodiment, after the silicon local oxidation isolation structure 141 is prepared through the LOCOS process, it is possible to prepare the contact portion 142 by a deposition process.

In an embodiment, a conductivity type of the first field limiting ring 131 may be a second conductivity type (for example, a P type), but is not limited thereto.

In an embodiment, a conductivity type of the cutoff ring 134 may be a first conductivity type (for example, an N-type), but is not limited thereto.

In an embodiment, shown as FIG. 1, the electrode layer 15 is located on a side of the first insulating layer 14 away from the substrate 11. A material of the electrode layer 15 may comprise, but is not limited to, a metal material.

In an embodiment, shown as FIG. 1, the electrode layer 15 comprises a first field plate 151, the first field plate 151 covers a portion of the main junction structure 12 close to the plurality of field limiting ring structures 13 and at least one first field limiting ring 131 close to the main junction structure 12, and the first field plate 151 is electrically connected to the main junction structure 12. The first field limiting ring 131 covered by the first field plate 151 is not electrically connected to the first field plate 151.

In one embodiment, a material of the electrode layer 15 may comprise a copper-aluminum alloy, obtained by adopting a Physical Vapor Deposition (PVD) process to deposit an aluminum alloy target. However, the material of the electrode layer 15 is not limited to the copper-aluminum alloy.

It should be noted that, the more the first field limiting rings 131 covered by the first field plate 151 are, the lower a maximum breakdown voltage of the device is. Therefore, the amount of the first field limiting rings 131 covered by the first field plate 151 may be determined according to a lowest breakdown voltage value of the power semiconductor device.

In an embodiment, shown as FIG. 1, the first field plate 151 covers a portion of the main junction structure 12 close to the plurality of field limiting ring structures 13 and a first field limiting ring 131 close to the main junction structure 12.

In an embodiment, shown as FIG. 1, the plurality of field limiting ring structures 13 further comprise at least one second field limiting ring 132, in an embodiment, comprising two second field limiting rings 132.

It should be noted that both the first field limiting ring 131 and the second field limiting ring 132 are same in both structure and preparation process, for ease of expression, a field limiting ring covered by the first field plate 151 is named as the first field limiting ring 131, while another field limiting ring not covered by the first field plate 151 is named as the second field limiting ring 132.

In an embodiment, shown as FIG. 1, the at least one second field limiting ring 132 is arranged between the first field limiting ring 131 and the cutoff ring 134, while being isolated in the first direction. The first field limiting ring 131, the second field limiting ring 132, and the cutoff ring 134 are arranged in an isolated manner in the first direction.

In an embodiment, a conductivity type of the second field limiting ring 132 may be a second conductivity type (that is, a P-type), but is not limited thereto.

In an embodiment, shown as FIG. 1, the electrode layer 15 further comprises at least one second field plate 152 and at least one third field plate 153, in an embodiment, the electrode layer 15 comprises two second field plates 152 and a third field plate 153.

Shown as FIG. 1, the at least one second field plate 152 is arranged on the side of the first insulating layer 14 away from the substrate 11. The first field plate 151 is insulated from the at least one second field plate 152 in the first direction, an amount of the second field plates 152 is as same as an amount of the second field limiting rings 132, the at least one second field plate 152 is electrically connected to the at least one second field limiting ring 132 in a one-to-one correspondence, and for each pair of the second field plate 152 and the second field limiting ring 132 being electrically connected, the second field plate 152 covers at least a portion of the second field limiting ring 132. In an embodiment, the first field plate 151 is arranged insulating from two second field plates 152 in the first direction, and the two second field plates 152 are electrically connected to two second field limiting rings 132 in a one-to-one correspondence.

Shown as FIG. 1, the third field plate 153 is arranged on the side of the first insulating layer 14 away from the substrate 11. The first field plate 151, the at least one second field plate 152 and the at least one third field plate 153 are arranged insulating to each other in the first direction, an amount of the third field plates 153 is as same as an amount of the cutoff rings 134, the at least one third field plate 153 is electrically connected to the at least one cutoff ring 134 in a one-to-one correspondence, and for a pair of the third field plate 153 and the cutoff ring 134 being electrically connected, the third field plate 153 covers at least a portion of the cutoff ring 134. In an embodiment, the first field plate 151, two second field plates 152 and one third field plate 153 are arranged insulating from each other in the first direction, the one third field plate 153 is electrically connected to one cutoff ring 134, and covering at least a portion of the cutoff ring 134.

In an embodiment, shown as FIG. 1, the power semiconductor device further comprises a plurality of contacts 18.

Shown as FIG. 1, the plurality of contacts 18 penetrate the first insulating layer 14. Specifically, each of the plurality of contacts 18 penetrates a different contact portion 142 respectively. The plurality of contacts 18 comprise a first contact 181, at least one second contact 182 and at least one third contact 183. In an embodiment, the plurality of contacts 18 comprise one first contact 181, two second contacts 182 and one third contact 183.

Shown as FIG. 1, the first field plate 151 is in contact with the main junction structure 12 through the first contact 181. An orthographic projection of the first contact 181 on the substrate 11 is located within an orthographic projection of the main junction structure 12 on the substrate 11, and is also located within an orthographic projection of the first field plate 151 on the substrate 11.

Shown as FIG. 1, the at least one second field plate 152 are in contact with different field limiting rings through different second contacts 182. In an embodiment, the two second field plates 152 are in contact with different second field limiting rings 132 through different second contacts 182 respectively.

Shown as FIG. 1, the at least one third field plate 153 are in contact with different cutoff rings through different third contacts 183. In an embodiment, one third field plates 152 is in contact with the cutoff ring 134 through the third contact 183 respectively.

In an embodiment, shown as FIG. 1, the power semiconductor device further comprises a second insulating layer 19.

Shown as FIG. 1, the second insulating layer 19 is located on the side of the first insulating layer 14 away from the substrate 11. The second insulating layer 19 comprises a plurality of insulating parts 191. An insulating part 191 is arranged between two adjacent field plates of the first field plate 151, the at least one second field plate 152 and the at least one third field plate 153.

In an embodiment, the second insulating layer 19 can comprise a passivation layer and a protective layer, the passivation layer is arranged on the side of the first insulating layer 14 away from the substrate 11, and the protective layer is located on a side of the passivation layer away from the substrate 11. The second insulating layer 19 may not be limited to a combination of the passivation layer and the protective layer.

In an embodiment, a material of the passivation layer may comprise, but not limited to, silicon nitride, and the passivation layer may be prepared by a Plasma-Enhanced Chemical Vapor Deposition (PECVD) process.

In an embodiment, a material of the protective layer may comprise, but not limited to, polyimide, and the protective layer may be prepared by a coating process.

In the present embodiment, since the electrode layer 15 comprises the first field plate 151, while the first field plate 151 covers both a portion of the main junction structure 12 close to the plurality of field limiting ring structures 13 and at least one first field limiting ring 131 close to the main junction structure 12, also the first field plate 151 is electrically connected to the main junction structure 12 instead of being electrically connected to the first field limiting ring 131 covered thereby. In such a way, when the device is in use, a voltage of a field plate of the first field limiting ring 131 is a voltage of a field plate of the main junction structure 12, that is, 0 Volt, which equals to applying a higher negative voltage to a bias field plate (the first field plate 151), being able to further reduce a peak value of the electric field near a surface of the main junction. Moreover, since the first field plate 151 covers a larger area, an effective area acting on a surface of the substrate 11 is also increased, resulting in more carriers being rejected, thereby reducing the peak value of the electric field near a surface of a main junction. Meanwhile, an electric field intensity inside the substrate 11 will be improved, thereby a maximum breakdown voltage of the device will also be improved in a whole.

Moreover, since the main junction structure 12 and a plurality of field limiting rings close to the cell region have a short distance from the cell, an electric field at a corner of the plurality of field limiting rings and a corner of an edge of the main junction structure 12 in a layout is larger, having a stronger distortion, thus a destructive breakdown is more likely to occur. In the present application, a maximum peak of a surface electric field is transferred from the edge of the main junction structure 12 to the first field limiting ring 131, the second field limiting ring 132, or a plurality of other field limiting rings, it is able to increase a distance between the maximum peak of the surface electric field and the cell, increase a radius of curvature of a corner at the maximum peak of the surface electric field, thus being able to further reduce the maximum peak of the electric field at the corner of the device, reduce an occurrence of dielectric breakdown, and improve the reliability of the device against the dielectric breakdown.

FIG. 2 illustrates a schematic structural diagram on an insulated gate bipolar transistor (IGBT) in the prior art. Shown as FIG. 2, the IGBT comprises: a P-type main junction 100, a plurality of fourth field limiting rings 101, a plurality of fourth contacts 102, a silicon local oxidation isolation portion 103, an N-type cutoff ring 104, a thin oxide layer 105, an insulating dielectric layer 106, a plurality of metal field plates 107, an N-type drift region 108, an N+- type cutoff layer 109, and a P-type collector region 110. The plurality of metal field plate 107 connecting to the P-type main junction 100 do not cover the plurality of fourth field limiting rings 101, while each of the plurality of fourth field limiting rings 101 has a metal field plate 107 electrically connected, and the N-type cutoff ring 104 also has a metal field plate 107 electrically connected. There is a thick oxide layer (the silicon local oxidation isolation portion 103) under the plurality of metal field plate 107, applied to weakening the electric field strength and preventing the device from being broken down under the high electric field of the field plate, resulting in failure of the device.

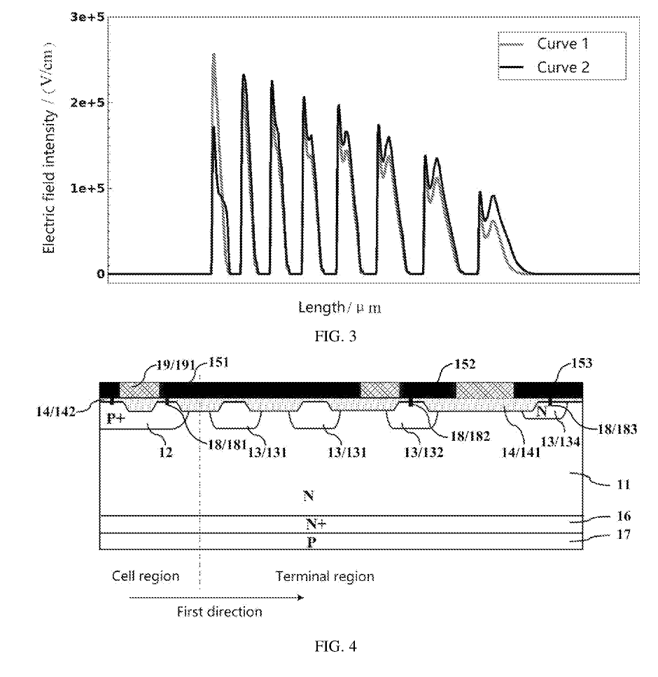

FIG. 3 illustrates a schematic diagram on a one-dimensional electric field distribution comparison between the power semiconductor device shown in FIG. 1 and the IGBT in the prior art shown in FIG. 2. Wherein curve 1 is an electric field distribution curve of the IGBP in the prior art shown in FIG. 2, and curve 2 is an electric field distribution curve of the power semiconductor device shown in FIG. 1. In FIG. 3, a horizontal axis represents a length in a transverse direction of the device, an origin is at a place of the main junction structure 12, having a unit of micron, a longitudinal axis is an electric field intensity, with a unit of volts per centimeter (V/cm ).

When simulating the electric field of the power semiconductor device shown in FIG. 1, an actual situation has been considered that there is a charge in the first insulating layer 14 (an oxide layer). It can be seen from FIG. 3 that a surface electric field of the power semiconductor device in the present application shown as FIG. 1 has an electric field intensity lower than that of the IGBT in the prior art as shown in FIG. 2, and a maximum electric field intensity occurs at a second peak value of the electric field (from left to right), that is, having been moved from a curved junction at the edge of the P-type main junction 100 in the prior art to the first field limiting ring 131 (a first of the field limiting ring structure 13), thus reducing a maximum electric field strength, while increasing a curvature radius of the corner in the maximum peak value of the surface electric field, further reducing the maximum peak value of the electric field at the corner of the device, and further reducing a breakdown risk, while enhancing a reliability against the dielectric breakdown.

In addition, a breakdown voltage of the IGBT in the prior art shown in FIG. 2 is 1192V, while a structural breakdown voltage of the power semiconductor device in the present application shown in FIG. 1 is 1317V, thus the present application is able to enhance the reliability while improving a breakdown voltage level.

All above, the technical solution provided by the present application, is able to improve the breakdown voltage and the dielectric breakdown reliability of the device in use by optimizing the structure of the field plate, changing the distribution of both the potential and an electric field flux distribution, before redistributing the surface electric field, without increasing the area of the power semiconductor device.

Another embodiment of the present application provides a power semiconductor device, shown as FIG. 4, unlike the embodiment shown in FIG. 1, in the present embodiment, the power semiconductor device has a first field plate 151 covering a portion of the main junction structure 12 near the field limiting ring structure 13 and two first field limiting rings 131 near the main junction structure 12. The first field plate 151 is in contact with the main junction structure 12 through the first contact 181, and two first field limiting rings 131 covered by the first field plate 151 are not electrically connected to the first field plate 151. FIG. 5 illustrates a schematic diagram comparing the one-dimensional electric field distribution of the power semiconductor device shown in FIG. 4 with the IGBT in the related art shown in FIG. 2. Wherein curve 1 is the electric field distribution curve of the IGBT in the prior art shown in FIG. 2, and curve 3 is an electric field distribution curve of the power semiconductor device shown in FIG. 4. In FIG. 5, a horizontal axis represents a length in a transverse direction of the device, an origin is at a place of the main junction structure 12, having a unit of micron, a longitudinal axis is an electric field intensity, with a unit of volts per centimeter (V/cm ).

When simulating the electric field of the power semiconductor device shown in FIG. 4, an actual situation has been considered that there is a charge in the first insulating layer 14 (an oxide layer). It can be seen from FIG. 5 that a surface electric field of the power semiconductor device in the present application shown as FIG. 4 has an electric field intensity lower than that of the IGBT in the prior art as shown in FIG. 2, and a maximum electric field intensity occurs at a fourth peak value of the electric field (from left to right), that is, having been moved from a curved junction at the edge of the P-type main junction 100 in the prior art to the second field limiting ring 132 (a third of the field limiting ring structure 13), thus reducing the maximum electric field strength, while increasing the curvature radius of the corner at the maximum peak value of the surface electric field, further reducing the maximum peak of the electric field at the corner of the device, and further reducing a breakdown risk, but enhancing reliability of avoiding the dielectric breakdown. In addition, a breakdown voltage of the IGBT in the prior art is 1192V, while a structural breakdown voltage of the power semiconductor device in the present application shown in FIG. 4 is 1300V, thus the present application is able to enhance the reliability while improving a breakdown voltage level.

Further, due to the main junction structure 12 being easy to have a charge carrier drifted and accumulated, thus a high electric field on place is easy to have a thermal breakdown before causing a device failure. The technical solution provided in the present application has dispersed the electric field strength at the main junction structure 12 and enhanced an electric field strength of a plurality of field limiting rings far away from the main junction structure 12, ensuring both reliability and breakdown voltage.

All above, the technical solution provided by the present application, is able to further improve the breakdown voltage and the dielectric breakdown reliability of the device in use by optimizing the structure of the field plate and changing the distribution of both the potential and an electric field flux distribution, before redistributing the surface electric field.

Another implementation of the present application provides a preparation method for the power semiconductor device, applied to preparing the power semiconductor device in anyone embodiment stated above. Shown as FIG. 6, the preparation method for the power semiconductor device comprises a plurality of following steps S601 to S604:

step S601: providing the substrate;

In the present step, it could be a substrate 11 of the first conductivity type (e.g., an N-type) being provided. The substrate 11 is divided into a cell region and a terminal region, and the terminal region being located on a periphery of the cell region.

Step S602: forming the main junction structure 12 and the plurality of field limiting ring structures 13 on a surface of the first side of the substrate 11;

Wherein the plurality of field limiting ring structures 13 comprise the first field limited ring 131, the second field limited ring 132, and the cutoff ring 134.

In the present step, it is possible to adopt a photolithography process to define a main junction region where the main junction structure 12 is located on the surface of the first side of the substrate 11, before adopting an ion implantation process to perform an ion implantation to main junction region and forming the main junction structure 12.

In the present step, it is also possible to adopt a field limiting ring mask plate to define a field limiting ring region where the plurality of field limiting ring structures 13 are located on an N-type substrate 11. The field limiting ring region comprises a first field limiting ring region where the first field limiting ring 131 is located, a second field limiting ring region where the second field limiting ring 132 is located, and a cutoff ring region where the cutoff ring 134 is located.

Followed by adopting an ion implantation process to inject a P-type doping into the first field limiting ring region and the second field limiting ring region, before performing a thermal popcorn to form the first field limiting ring 131 and the second field limiting ring 132, and adopting an ion implantation process to inject a P-type doping into the cutoff ring region to form the cutoff ring 134. In an embodiment, the P-type doping may be, but is not limited to, boron (Boron) ion or gallium (Ga) ion. An N-type doping may be, but not limited to, phosphorus (P) ion, arsenic (As) ion or antimony (Sb) ion.

Step S603: forming the first insulating layer 14 on the side of both the main junction structure 12 and the plurality of field limiting ring structures 13 away from the substrate 11;

Wherein the first insulating layer 14 comprises: a plurality of silicon local oxidation isolation structures 141 and a plurality of contact portions 142. The plurality of silicon local oxidation isolation structures 141 are applied to isolating two adjacent structures in the main junction structure 12 and the plurality of field limiting ring structures 13. Each of the main junction structure 12 and the plurality of field limiting ring structures 13 has a contact portion 142 arranged. A part of the contact portion 142 is applied to providing a plurality of contact 18.

In an embodiment, it is possible to first prepare the plurality of silicon local oxidation isolation structures 141 through a silicon local oxidation isolation process, then prepare the plurality of contact portions 142 through a deposition process, before obtaining the first insulation layer 14.

In an embodiment, shown as FIG. 1, when the surface of the silicon local oxidation isolation structure 141 away from the substrate 11 is planar, after preparing and obtaining an initial isolation structure by adopting the silicon local oxidation isolation process, it is possible to perform a chemical mechanical planarization (CMP) to the initial isolation structure, before obtaining the silicon local oxidation isolation structure 141 having been polished.

In another embodiment, the silicon local oxidation isolation structure 141 may be an initial isolation structure prepared by adopting a silicon local oxidation isolation process, which is a complete initial isolation structure without CMP.

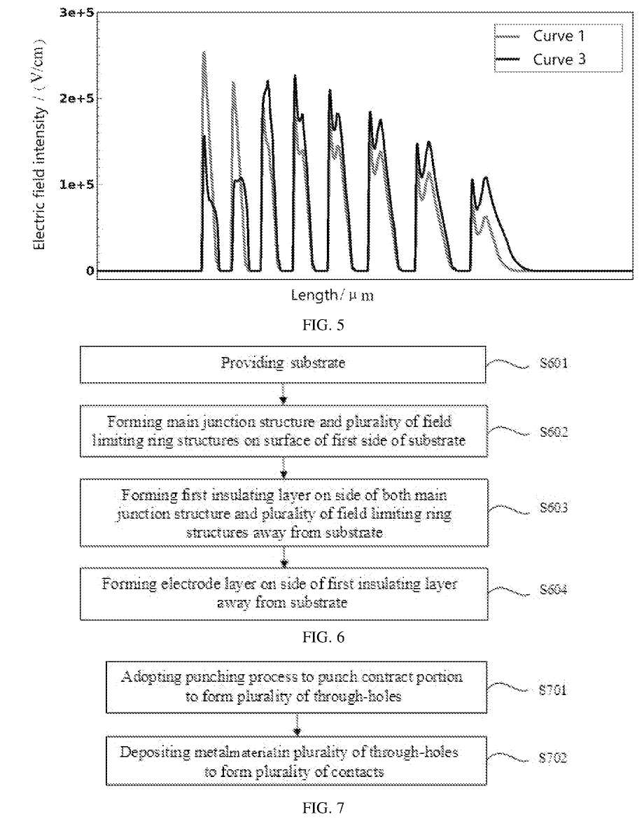

In an embodiment, after forming the first insulating layer 14, shown as FIG. 7, it further comprises a plurality of following steps S701 to S702.

Step S701: adopting a punching process to punch the contact portion to form a plurality of through holes.

In the present step, it is only necessary to punch a contact portion 142 on the main junction structure 12, a contact portion 142 on the second field limiting ring, and a contact portion 142 on the cutoff ring 134 to form the plurality of through holes. Comparing to the prior art, only a position of the through holes being punched is different but a process adopted is same, thus there is no additional process required.

Step S702: depositing a metal material into the plurality of through holes to form a plurality of contacts.

In the present application, a process of preparing the plurality of contacts 18 is as same as that in the prior art, thus no additional process is required.

Step S604, forming the electrode layer 15 on the side of the first insulating layer 14 away from the substrate 11.

In the present step, it is possible to adopt a field plate mask plate to deposit a metal material on the side of the first insulating layer 14 away from the substrate 11 to form the electrode layer 15.

In the present application, a process for forming the electrode layer 15 is as same as a process for forming a metal field plate in the prior art, except that a field plate mask plate adopted is different, thus no additional process is required.

In an embodiment, the step S702 and the step S604 belong to a same process, that is, it is possible to adopt a deposition process to deposit a metal material into a plurality of through holes, before forming the plurality of contacts 18, at a same time, forming the electrode layer 15 on the side of the first insulating layer 14 away from the substrate 11. In an embodiment, after forming the electrode layer 15, a second insulating layer 19 is formed on the side of the first insulating layer 14 away from the substrate 11.

In an embodiment, when the second insulating layer 19 comprises the passivation layer and the protective layer as described above, it may first adopt a PECVD (Plasma Enhanced Chemical Vapor Deposition) process to from the passivation layer on the side of the first insulating layer 14 away from the substrate 11, then adopt a coating process to form the protective layer on the side of the passivation layer 14 away from the substrate 11. In the present application, the process for preparing the power semiconductor device is simple, and it is enough to adopt a traditional preparation process, without any additional process, thus the process cycle and cost will not be increased.

In the present application, the terms "first" and "second" are for description purposes only and are not to be construed as indicating or implying relative importance. The term "a plurality of" refers to two or more, unless otherwise expressly defined.

While the embodiments of the present application have been described in detail, it will be apparent to those skilled in the art that various modifications and changes can be made to the embodiments. However, it is to be understood that such modifications and variations are within the scope and spirit of the present invention as described in the appended claims. Furthermore, the present invention described herein is susceptible to other embodiments and may be embodied or carried out in various ways.

What is claimed is:

1. A power semiconductor device, wherein comprising:
a substrate, having a first side and a second side opposite to the first side, comprising a cell region and a terminal region disposed respectively in a first direction;
a main junction structure, arranged on the first side of the substrate and located in the cell region;
a plurality of field limiting ring structures, arranged on the first side of the substrate and located in the terminal region, while being arranged in an isolated manner along the first direction; comprising at least one field limiting ring and at least one cutoff ring, wherein the at least one cutoff ring is arranged on a side away from the main junction structure in the first direction;
a first insulating layer, arranged on a side of both the main junction structure and the plurality of field limiting ring structures away from the substrate;
a first field plate, arranged on a side of the first insulating layer away from the substrate, covering one portion of the main junction structure close to the plurality of field limiting ring structures, and one or two of the at least one field limiting ring close to the main junction structure, while being connected electrically to the main junction structure;
at least one second field plate, arranged on the side of the first insulating layer away from the substrate and insulated from the first field plate in the first direction, having an amount as same as an amount of the at least one field limiting ring not being covered by the first field plate, and covering at least partially a corresponding one of the at least one field limiting ring while electrically connected to each other in a one-to-one correspondence manner;
further comprising a field termination layer, arranged on the second side of the substrate, having a first conductivity type that a doping concentration greater is than that of the substrate.
further comprising a collector region, arranged on a side of the field termination layer away from the substrate, having a second conductivity type reverse to the first conductivity type.

2. The power semiconductor device according to claim 1, wherein an amount of the at least one field limiting ring covered by the first field plate is determined according to a minimum breakdown voltage value of the power semiconductor device.

3. The power semiconductor device according to claim 1, wherein the first field plate covers one of the at least one field limiting ring close to the main junction structure.

4. The power semiconductor device according to claim 1, wherein the first field plate covers two of the at least one field limiting ring close to the main junction structure.

5. The power semiconductor device according to claim 4, wherein further comprising:
at least one third field plate, arranged on the side of the first insulating layer away from the substrate; the first field plate, the at least one second field plate and the at least one third field plate being insulated from each other in the first direction, an amount of the at least one third field plate being as same as an amount of the at least one cutoff ring, the at least one third field plate and the at least one cutoff ring being connected electrically to each other in a one-to-one correspondence, and at least covering a portion of the cutoff ring corresponding thereto.

6. The power semiconductor device according to claim 5, wherein further comprising:
a plurality of contacts penetrating through the first insulating layer, comprising a first contact, at least one second contact and at least one third contact, the first field plate being in contact with the main junction structure through the first contact, the at least one second field plate are in contact with different second field limiting rings through different second contacts, and each of the at least one third field plate being in contact with a corresponding cutoff ring through a corresponding third contact.

7. The power semiconductor device according to claim 6, wherein the first insulating layer comprising:
a plurality of silicon local oxidation isolation structures and a plurality of contact portions, the plurality of silicon local oxidation isolation structures and the plurality of contact portions being arranged alternately, each of the plurality of silicon local oxidation isolation structures being arranged respectively between adjacent two of the plurality of field limiting ring structures and the main junction structure, the plurality of contact portions being corresponding to the plurality of contacts, penetrating through the plurality of silicon local oxidation isolation structures, and corresponding to the main junction structure and a part of the plurality of field limiting ring structures.

8. The power semiconductor device according to claim 5, wherein further comprising:
a second insulating layer, arranged on the side of the first insulating layer away from the substrate, comprising a plurality of insulating portions, arranged respectively between adjacent two field plates of the first field plate, the at least one second field plate, and the at least one third field plate.

9. A preparation method for a power semiconductor device, applied to preparing the power semiconductor device according to claim 1, wherein comprising:
providing the substrate;
forming the main junction structure and the plurality of field limiting ring structures on a surface of the first side of the substrate;
forming the first insulating layer on the side of both the main junction structure and the plurality of field limiting ring structures away from the substrate;
forming the electrode layer on the side of the first insulating layer away from the substrate.

10. The preparation method according to claim 9, wherein
when the power semiconductor device comprises a plurality of contacts and the first insulating layer comprises a plurality of contact portions, after forming the first insulating layer on the side of both the main junction structure and the plurality of field limiting ring structures away from the substrate, but before forming the electrode layer on the side of the first insulating layer away from the substrate, further comprising:
adopting a punching process to punch the contact portion to form a plurality of through holes;
depositing a metal material into the plurality of through holes to form a plurality of contacts, wherein both a process of depositing the metal material into the plurality of through holes to form the plurality of contacts, and a process of forming the electrode layer on the side of the first insulating layer away from the substrate are performed in a same process

11. The preparation method according to claim 9, wherein an amount of the at least one field limiting ring covered by the first field plate is determined according to a minimum breakdown voltage value of the power semiconductor device.

12. The preparation method according to claim 11, wherein
when the power semiconductor device comprises a plurality of contacts and the first insulating layer comprises a plurality of contact portions, after forming the first insulating layer on the side of both the main junction structure and the plurality of field limiting ring structures away from the substrate, but before forming the electrode layer on the side of the first insulating layer away from the substrate, further comprising:
adopting a punching process to punch the contact portion to form a plurality of through holes;
depositing a metal material into the plurality of through holes to form a plurality of contacts, wherein both a process of depositing the metal material into the plurality of through
holes to form the plurality of contacts, and a process of forming the electrode layer on the side of the first insulating layer away from the substrate are performed in a same process

13. The preparation method according to claim 9, wherein the first field plate covers one of the at least one field limiting ring close to the main junction structure.

14. The preparation method according to claim 13, wherein
when the power semiconductor device comprises a plurality of contacts and the first insulating layer comprises a plurality of contact portions, after forming the first insulating layer on the side of both the main junction structure and the plurality of field limiting ring structures away from the substrate, but before forming the electrode layer on the side of the first insulating layer away from the substrate, further comprising:
adopting a punching process to punch the contact portion to form a plurality of through holes;
depositing a metal material into the plurality of through holes to form a plurality of contacts, wherein both a process of depositing the metal material into the plurality of through holes to form the plurality of contacts, and a process of forming the electrode layer on the side of the first insulating layer away from the substrate are performed in a same process.

15. The preparation method according to claim 9, wherein the first field plate covers two of the at least one field limiting ring close to the main junction structure.

16. The preparation method according to claim 15, wherein further comprising:
at least one third field plate, arranged on the side of the first insulating layer away from the substrate; the first field plate, the at least one second field plate and the at least one third field plate being insulated from each other in the first direction, an amount of the at least one third field plate being as same as an amount of the at least one cutoff ring, the at least one third field plate and the at least one cutoff ring being connected electrically to each other in a one-to-one correspondence, and at least covering a portion of the cutoff ring corresponding thereto.

17. The preparation method according to claim 16, wherein a plurality of contacts penetrating through the first insulating layer, comprising a first contact, at least one second contact and at least one third contact, the first field plate being in contact with the main junction structure through the first contact, the at least one second field plate are in contact with different second field limiting rings through different second contacts, and each of the at least one third field plate being in contact with a corresponding cutoff ring through a corresponding third contact.

18. The preparation method according to claim 17, wherein
when the power semiconductor device comprises a plurality of contacts and the first insulating layer comprises a plurality of contact portions, after forming the first insulating layer on the side of both the main junction structure and the plurality of field limiting ring structures away from the substrate, but before forming the electrode layer on the side of the first insulating layer away from the substrate, further comprising:
adopting a punching process to punch the contact portion to form a plurality of through holes;
depositing a metal material into the plurality of through holes to form a plurality of contacts, wherein both a process of depositing the metal material into the plurality of through holes to form the plurality of contacts, and a process of forming the electrode layer on the side of the first insulating layer away from the substrate are performed in a same process.

19. The preparation method according to claim 9, wherein a plurality of silicon local oxidation isolation structures and a plurality of contact portions, the plurality of silicon local oxidation isolation structures and the plurality of contact portions being arranged alternately, each of the plurality of silicon local oxidation isolation structures being arranged respectively between adjacent two of the plurality of field limiting ring structures and the main junction structure, the plurality of contact portions being corresponding to the plurality of contacts, penetrating through the plurality of silicon local oxidation isolation structures, and corresponding to the main junction structure and a part of the plurality of field limiting ring structures.

20. The preparation method according to claim 9, wherein further comprising:
a second insulating layer, arranged on the side of the first insulating layer away from the substrate, comprising a plurality of insulating portions, arranged respectively between adjacent two field plates of the first field plate, the at least one second field plate, and the at least one third field plate.
